(19) United States
(12) Patent Application Publication
(10) Pub. No.: US 2022/0074866 A1
(43) Pub. Date: Mar. 10, 2022

(54) MACRO AND MICRO INSPECTION APPARATUS AND INSPECTION METHOD

(71) Applicant: MPI CORPORATION, CHU-PEI CITY (TW)

(72) Inventors: CHEN-YANG TSAI, CHU-PEI CITY (TW); WEI-MAO CHEN, CHU-PEI CITY (TW); HUAN-CHUN HSIEH, CHU-PEI CITY (TW)

(73) Assignee: MPI CORPORATION, CHU-PEI CITY (TW)

(21) Appl. No.: 17/469,273

(22) Filed: Sep. 8, 2021

Related U.S. Application Data
(60) Provisional application No. 63/075,835, filed on Sep. 9, 2020.

(30) Foreign Application Priority Data
Aug. 19, 2021 (TW) 110130725

(51) Int. Cl. G01N 21/88; G01N 21/95; B25J 11/00; H04N 5/247

(52) U.S. Cl. CPC G01N 21/8851; H04N 5/247; B25J 11/0095; G01N 21/9501

(57) ABSTRACT

A macro and micro inspection apparatus includes a macro inspection station including a housing, a robot arm and a visual recognition system, and a device under test storage station and a micro inspection station disposed on two sides of the macro inspection station, respectively. The robot arm including an end effector adapted for carrying and turning over a device under test is disposed in the housing in a way that the end effector enables to enter the device under test storage station and the micro inspection station. The visual recognition system includes at least one image capturing device disposed in the housing for shooting toward the end effector for capturing the image of the device under test. The invention, which also provides an inspection method using the inspection apparatus, is structurally simple, space-saving, avoids problems caused by manual inspection, and brings high inspection efficiency.

### BACKGROUND OF THE INVENTION

### 1. Field of the Invention

The present invention relates generally to electronic component inspection apparatus and more particularly, to an inspection apparatus which integrates macro inspection and micro inspection, and an inspection method thereof.

### 2. Description of the Related Art

In the conventional wafer inspection process, macro inspection is usually performed first. That is, a quality inspector observes the wafer by naked eyes and determines whether the appearance of the wafer is flawed. If the appearance of the wafer is flawless, micro inspection is then performed. That is, an inspection instrument is used to inspect the appearance, the electrical properties and/or optical characteristics of the dies of the wafer. However, the macro inspection performed manually may not only cause missed inspection or false inspection due to visual fatigue of the quality inspector, but also may cause wafer falling or wafer collision due to transporting negligence of the quality inspector, so as to cause material loss. In addition, between the macro inspection and the micro inspection, wafers need to be transferred, classified, and collected to wait. These procedures not only take up space, but also increase the time required for the overall inspection process.

US Patent Publication No. 2008/0285022 A1 disclosed an inspection apparatus which integrates macro inspection and micro inspection. Although the inspection apparatus can reduce the distance and time for transferring the device under test between the macro inspection and the micro inspection, the inspection apparatus needs a transferring robot to transfer the device under test to the inspection station, and also needs a rotary mechanism disposed in the inspection station to receive the device under test transferred by the transferring robot and rotate the device under test to a macro inspection part and a micro inspection part. In other words, the devices provided in the inspection apparatus for moving the device under test include the aforementioned transferring robot and rotary mechanism, which also quite take up space. Besides, the inspection station is equipped therein with the rotary mechanism, the macro inspection part and the micro inspection part, thereby complicated and crowded in its spatial arrangement. Furthermore, the macro inspection part needs two mechanisms to clamp the device under test when manual visual inspection is performed to the front and the back of the device under test, respectively. In other words, after the manual visual inspection is performed to the front of the device under test clamped by one of the mechanisms, it needs to change into the other mechanism to clamp the device under test so as to turn over the device under test, so that the manual visual inspection can be performed to the hack of the device under test. Therefore, the macro inspection part is also quite complicated in its structure and spatial arrangement.

### SUMMARY OF THE INVENTION

The present invention has been accomplished in view of the above-noted circumstances. It is an objective of the present invention to provide a macro and micro inspection apparatus and an inspection method thereof, which can avoid problems caused by manual inspection, and the inspection apparatus is structurally simple, space-saving, and brings high inspection efficiency.

To attain the above objective, the present invention provides a macro and micro inspection apparatus which includes a macro inspection station, a device under test storage station disposed on a side of the macro inspection station, and a micro inspection station disposed on another side of the macro inspection station. The macro inspection station includes a housing, a robot arm, and a visual recognition system. The robot arm includes an end effector adapted for carrying and turning over a device under test. The robot arm is disposed in the housing in a way that the end effector enables to enter the device under test storage station and the micro inspection station. The visual recognition system includes at least one image capturing device disposed in the housing to enable shooting toward the end effector for capturing the image of the device under test.

To attain the above objective, the present invention further provides an inspection method using the aforementioned macro and micro inspection apparatus, which includes the steps of:

taking out a said device under test from the device under test storage station to the macro inspection station by the end effector of the robot arm;

capturing the image of the device under test by the image capturing device of the visual recognition system to perform a macro inspection;

rotating the device under test by the robot arm, and capturing the image of the device under test which has been rotated by the image capturing device of the visual recognition system to perform another macro inspection; and if the result of the macro inspections performed by the visual recognition system is the device under test is unqualified, putting the device under test back to the device under test storage station by the robot arm; if the result of the macro inspections performed by the visual recognition system is the device under test is qualified, transferring the device under test to the micro inspection station by the robot arm for performing a micro inspection to the device under test in the micro inspection station.

As a result, the macro and micro inspection apparatus and the inspection method of the present invention only need a robot arm to transfer the device under test between the device under test storage station, the macro inspection station and the micro inspection station. Besides, the various actions the quality inspector performs for the macro inspection can be simulated in the macro inspection station by the robot arm performing various actions to the device under test, such as displacing, tilting, rotating, and so on, and cooperating with the visual recognition system, so as to attain the front inspection, back inspection, lateral inspection, oblique inspection, rotary inspection, light refection inspection, and so on. Therefore, the present invention doesn't need human labor to transfer the device under test or inspect the appearance of the device under test by the naked eyes, thereby prevented from the problems of missed inspection, false inspection, wafer falling, wafer collision, and so on, which may be caused by manual inspection. Besides, the present invention can steadily repeat the same macro inspection actions to attain great inspecting effect. Furthermore, the macro and micro inspection apparatus of the present invention is quite simple in structure and space-saving, and can connect the macro inspection with different micro inspection procedures or with device under test storage stations for the devices under test of different sizes. Therefore, according to the inspection requirements and the use environment, the most appropriate arrangement can be made to improve the machine utilization and reduce the transferring distance and waiting time between different procedures, thereby bringing high inspection efficiency.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given herein below and the accompanying drawings which are given by way of illustration only, and thus are not limitative of the present invention; and wherein:

FIG. 1 is a schematic view of a macro and micro inspection apparatus according to a first preferred embodiment of the present invention;

FIG. 2 is an assembled perspective view of a robot arm of the macro and micro inspection apparatus;

FIG. 3 is a partially enlarged view of FIG. 2, but further schematically showing a device under test, four image capturing devices and their fields of view;

FIG. 4 is a top view of FIG. 3;

FIG. 5 is similar to FIG. 4, but showing an arrangement with only three image capturing devices;

FIG. 6 is a perspective view showing another type of an end effector of the robot arm;

FIG. 7 is a flow chart of an inspection method using the macro and micro inspection apparatus;

FIG. 8 and FIG. 9 are schematic views showing an image capturing device shooting a device under test in a scanning manner;

FIG. 10 is a schematic view of a macro and micro inspection apparatus according to a second preferred embodiment of the present invention; and

FIG. 11 is a schematic view of a macro and micro inspection apparatus according to a third preferred embodiment of the present invention.

### DETAILED DESCRIPTION OF THE INVENTION

First of all, it is to be mentioned that same or similar reference numerals used in the following embodiments and the appendix drawings designate same or similar elements or the structural features thereof throughout the specification for the purpose of concise illustration of the present invention. It should be noticed that for the convenience of illustration, the components and the structure shown in the figures are not drawn according to the real scale and amount, and the features mentioned in each embodiment can be applied in the other embodiments if the application is possible in practice.

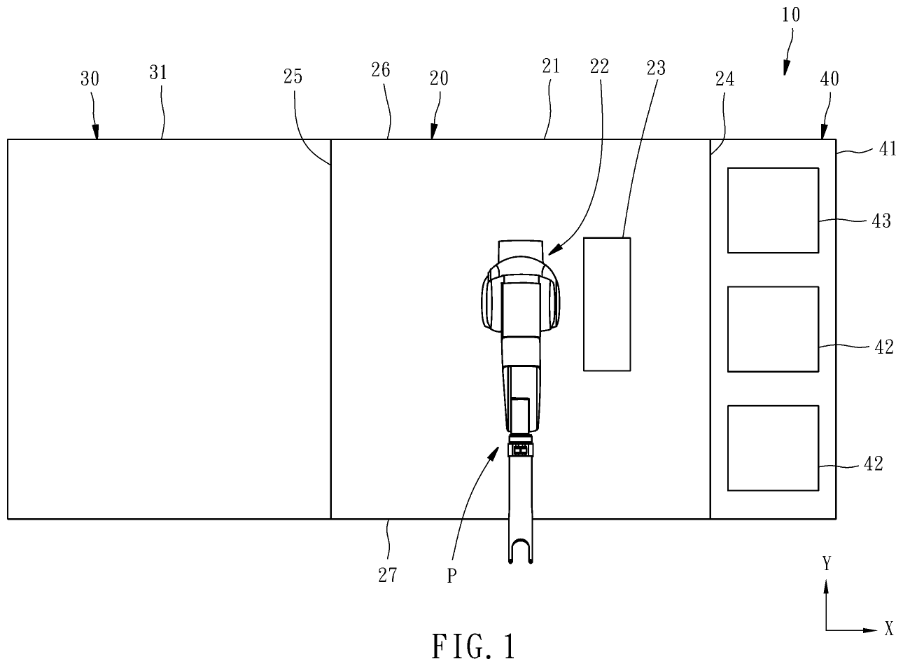

Referring to FIG. 1, a macro and micro inspection apparatus 10 according to a first preferred embodiment of the present invention includes a macro inspection station 20, a micro inspection station 30, and a device under test storage station 40.

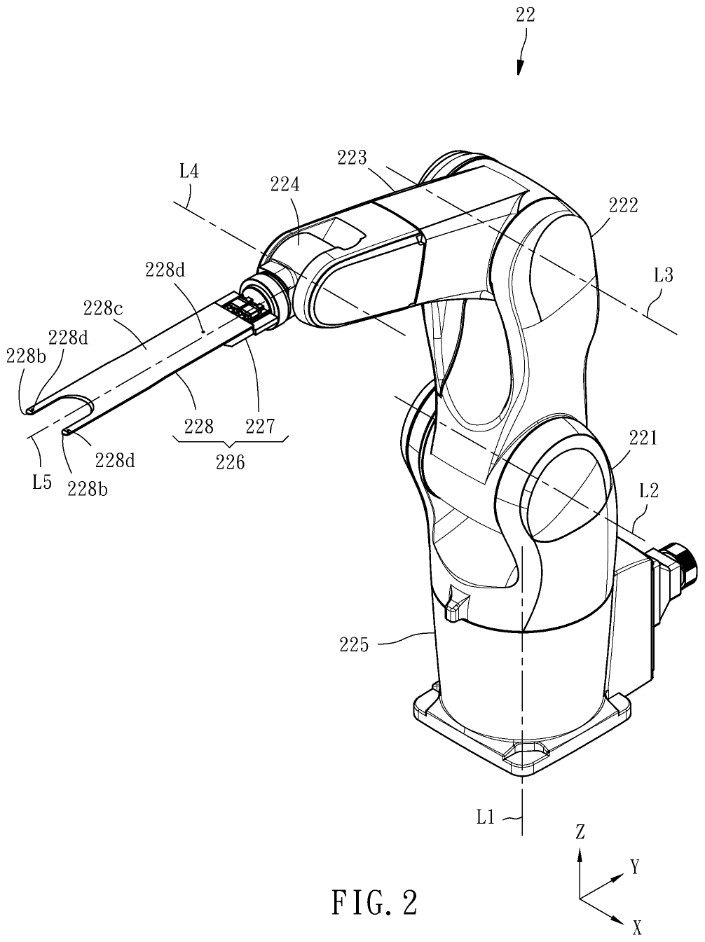

The macro inspection station 20 includes a housing 21, and a robot arm 22 and a visual recognition system 23 disposed in the housing 21. It should be mentioned here that FIG. 1 primarily shows the arrangement relation between the stations of the macro and micro inspection apparatus 10, so the members related to the aforementioned arrangement relation shown in FIG. 1 are only schematically drawn as rectangles except the robot arm 22. The structures of the robot arm 22 and the visual recognition system 23 will be specified in the following and illustrated in FIG. 2 to FIG. 5.

The micro inspection station 30 and the device under test storage station 40 each include a housing 31 and 41, and the housings 21, 31 and 41 communicate with each other. Specifically speaking, the macro and micro inspection apparatus 10 is defined with a first horizontal axis (X-axis and a second horizontal axis (Y-axis) perpendicular to the first horizontal axis (X-axis), The macro inspection station 20 has a first side 24 and a second side 25, which face toward two opposite directions of the first horizontal axis, i.e. the positive direction of X-axis and the negative direction of X-axis, and a third side 26 and a fourth side 27, which face toward two opposite directions of the second horizontal axis, i.e. the positive direction of Y-axis and the negative direction of Y-axis. The housing 41 of the device under test storage station 40 is connected to the first side 24 of the macro inspection station 20, and they communicate with each other at the connection thereof. The housing 31 of the micro inspection station 30 is connected to the second side 25 of the macro inspection station 20, and they communicate with each other at the connection thereof.

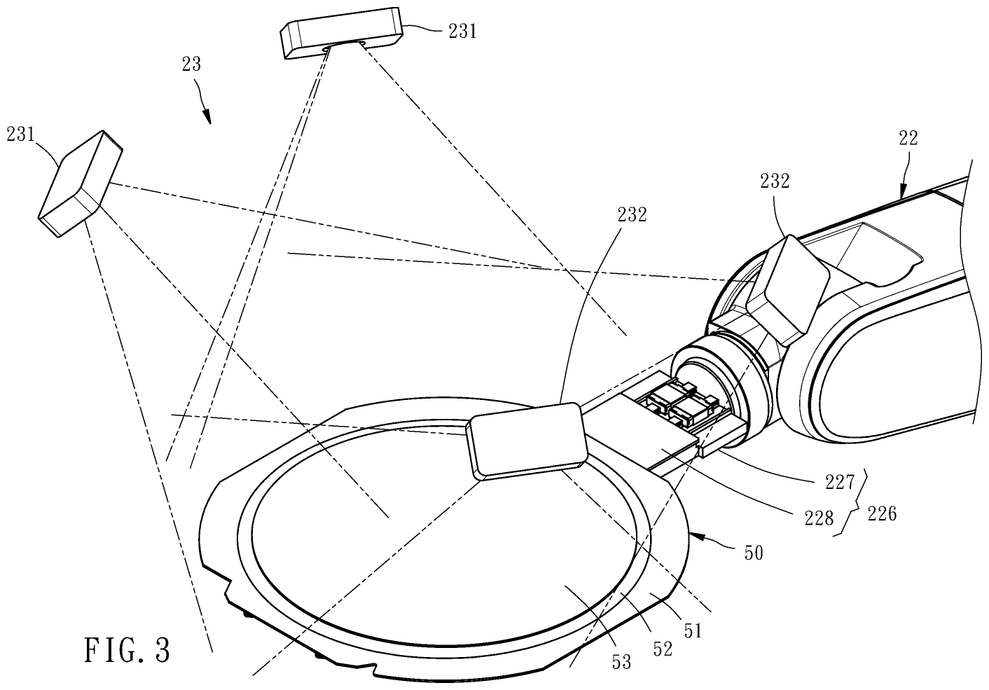

The device under test storage station 40 is primarily used for storing a plurality of devices under test to be inspected, and may be also used for storing the devices under test having to be reclaimed. The device under test storage station 40 in this embodiment is provided therein with two supply cassettes 42 and a reclaim cassette 43. The supply cassettes 42 and reclaim cassette 43 may be the conventional wafer cassettes, so the structure thereof needs not be specified hereinafter. The supply cassettes 42 and reclaim cassette 43 are the same in structure, but the two supply cassettes 42 are used for storing a plurality of devices under test to be inspected, enabling the macro and micro inspection apparatus 10 to continuously inspect a plurality of devices under test and thereby raising the inspection efficiency. The reclaim cassette 43 is used for storing the devices under test unqualified by the inspection result and thereby having to be reclaimed, which will be specified in the following. As shown in FIG. 3, the device under test 50 in this embodiment includes an iron ring 51, a flexible film 52, e.g. blue film, fixed to the iron ring 51, and a wafer 53 disposed on the flexible film 52 and not diced into separated dies yet. The macro and micro inspection apparatus 10 is adapted to firstly perform macro inspections to the wafer 53, i.e. check flaws on the appearance of the wafer, and then perform micro inspection, i.e. inspect the dies of the wafer in their appearances, electrical properties, optical characteristics, and so on. However, the macro and micro inspection apparatus 10 of the present invention is unlimited to inspect wafers.

The micro inspection station 30 may, but unlimited to, be an automated optical inspection system, also called AOI, for inspecting the optical characteristics of the dies of the wafer 53, such as LED dies. As described above, the technical features of the present invention primarily lie in the macro inspection station 20, and the arrangement relation between the stations. The inner structure of the micro inspection station 30 is less related to the technical features of the present invention and thereby will not be specified hereinafter, and therefore the inner structure of the micro inspection station 30 is not shown in the figures.

Referring to FIG. 2, the robot arm 22 includes first to fourth rotary arms 221-224, a base 225, and an end effector 226. The base 225 is disposed in the housing 21 movably along the first horizontal axis (X-axis), enabling the entirety of the robot arm 22 to move relative to the housing 21 along the first horizontal axis (X-axis). Specifically speaking, the housing 21 may be provided therein with a linear displacement assembly (not shown) arranged along the first horizontal axis (X-axis), and the robot arm 22 is disposed on the linear displacement assembly to be driven by the linear displacement assembly to move along the first horizontal axis (X-axis). The linear displacement assembly may be the conventional linear displacement assembly including a motor, a slideway, a slider, and so on, and thereby will not be specified hereinafter, and the linear displacement assembly is not shown in the figures. An end of the first rotary arm 221 is attached to the top end of the base 225 rotatably about a first imaginary axis L1. The first imaginary axis L1 may, but unlimited to, be parallel to Z-axis. An end of the second rotary arm 222 is attached to the other end of the first rotary arm 221 rotatably about a second imaginary axis L2. The second imaginary axis L2 is perpendicular to the first imaginary axis L1. An end of the third rotary arm 223 is attached to the other end of the second rotary arm 222 rotatably about a third imaginary axis L3. The third imaginary axis L3 is parallel to the second imaginary axis L2. An end of the fourth rotary arm 224 is attached to the other end of the third rotary arm 223 rotatably about a fourth imaginary axis L4. The fourth imaginary axis L4 is parallel to the second and third imaginary axes L2 and L3. An end of the end effector 226 is attached to the other end of the fourth rotary arm 224 rotatably about a fifth imaginary axis L5. The fifth imaginary axis L5 is perpendicular to the second to fourth imaginary axes L2-L4.

The end effector 226 shown in FIG. 2 to FIG. 5 includes a supporting seat 227 connected to the fourth rotary arm 224, and a fork-shaped board 228 fixed to the supporting seat 227, The fork-shaped board 228 includes an inner end 228a, two outer ends 228h, a carrying surface 228c, and three vacuum suction holes 228d provided on the carrying surface 228c and located adjacent to the inner end 228a and the two outer ends 228b respectively. The vacuum suction holes 228d communicate with each other and a vacuum source (not shown) through a channel (not shown) provided inside the fork-shaped board 228, thereby capable of being affected by the vacuum source to generate negative pressure, so as to attach the device under test 50 on the carrying surface 228c by vacuum suction.

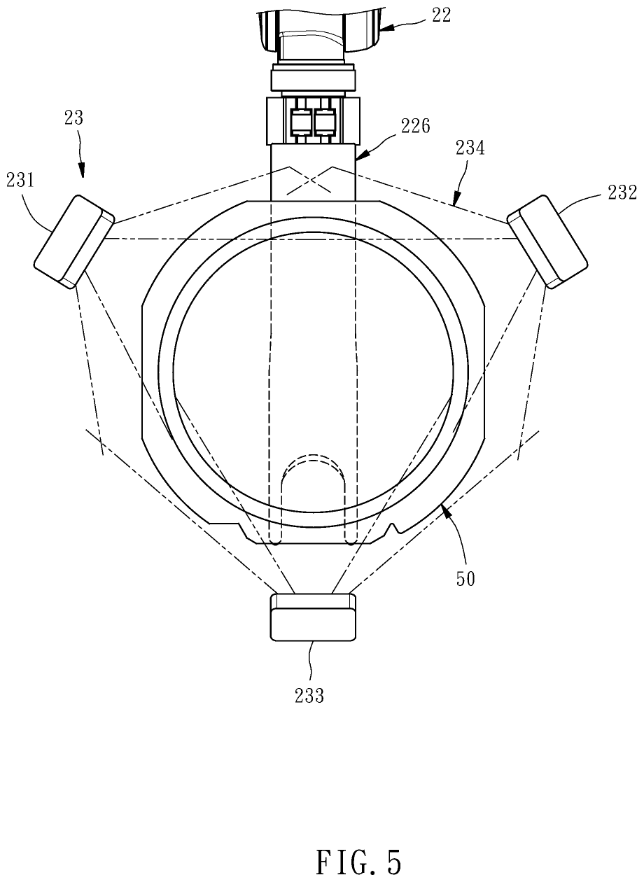

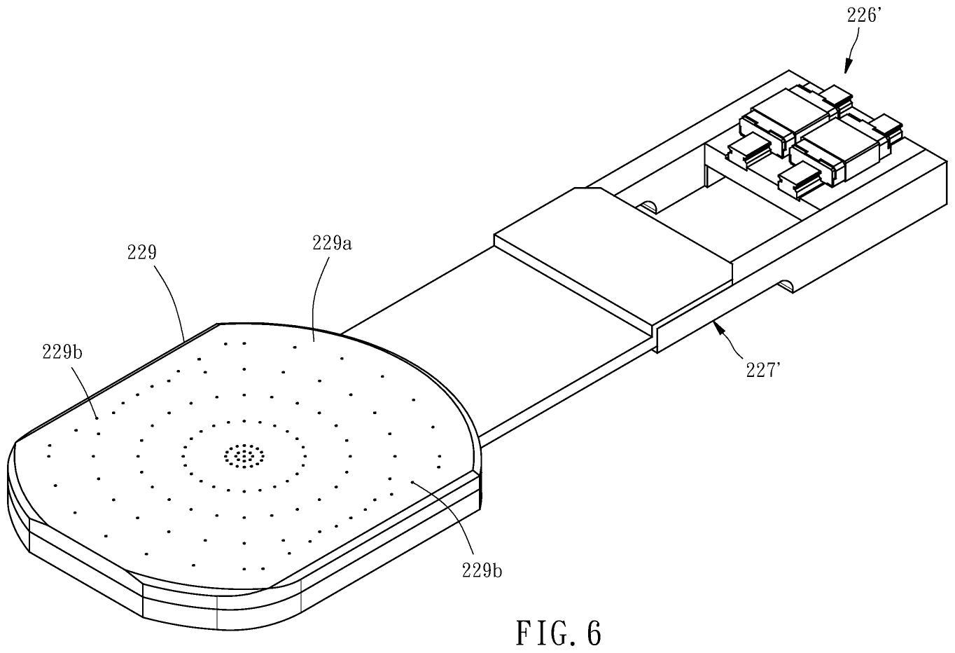

For the devices under test of different shapes and inspection requirements, the robot arm 22 may use the end effector of different types, such as the end effector 226′ as shown in FIG. 6. The end effector 226′ includes a supporting seat 227′ connected to the fourth rotary arm 224, and a carrying plate 229 disposed on an end portion of the supporting seat 227′. The carrying plate 229 is provided on a carrying surface 229a thereof with a plurality of vacuum suction holes 229b. The vacuum suction holes 229b communicate with each other and a vacuum source (not shown) through a channel (not shown) provided inside the supporting seat 227′ and the carrying plate 229, thereby capable of being affected by the vacuum source to generate negative pressure, so as to attach the device under test on the carrying surface 229a by vacuum suction. The robot arm 22 in the present invention is unlimited to use the above-described end effector 226 or 226′. For example, it may use a C-shaped end effector similar to that shown in FIG. 5 of US Patent Publication No. 2008/0285022 A1, which is mentioned in the description of the related art, for clamping the periphery of the wafer to expose both the top and bottom surfaces of the wafer. It will take only the above-described end effector 226 as an example for the following description, it can be known from the above-described structure that the robot arm 22 can generate six-axial motion, including linear displacement along an axis (X-axis) and rotation about five axes L1-L5. Specifically speaking, the robot arm 22 is movable relative to the housing 21 along the first horizontal axis (X-axis) from a middle position P as shown in FIG. 1 toward the two opposite directions of the first horizontal axis, i.e. the positive direction of X-axis and the negative direction of X-axis. In other words, the robot arm 22 located at the middle position P is movable toward the device under test storage station 40, and also movable toward the micro inspection station 30. Besides, the rotation of the robot arm 22 about the first imaginary axis L1 can change the extending direction of the combination of the first to fourth rotary arms 221-224 and the end effector 226. For example, it may be changed from the extending direction toward the fourth side 27 as shown in FIG. 1 to the direction facing toward the device under test storage station 40 by counterclockwise rotation for 90 degrees, or to the direction facing toward the micro inspection station 30 by clockwise rotation for 90 degrees. Furthermore, the rotations of the robot arm 22 about the second to fourth imaginary axes L2-L4 can change the extending direction of the end effector 226 in its angle with respect to Z-axis and its Z-axial position of height, and can make the end effector 226 leave or approach the base 225 on X-Y plane, i.e. extend outward or retract inward with the base 225 as the center. In addition, the rotation of the robot arm 22 about the fifth imaginary axis L5 can turn over the end effector 226 individually, so as to turn over the device under test 50 carried on the carrying surface 228c of the end effector 226.

By the aforementioned six-axial motion, the end effector 226 of the robot arm 22 can reach into various storage positions at different heights of each supply cassette 42 or reclaim cassette 43 of the device under test storage station 40, and the end effector 226 of the robot atm 22 can also reach into the micro inspection station 30 to place the device under test 50 at the position for the micro inspection. Besides, the end effector 226 of the robot atm 22 can also carry the device under test 50 and move to the position for being shot by the visual recognition system 23, that will be specified in the following.

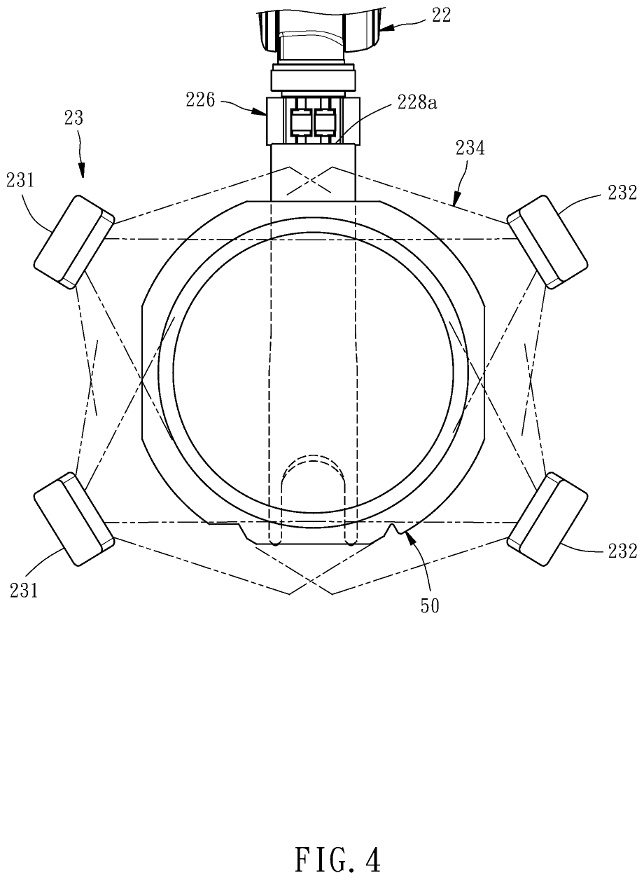

As shown in FIG. 3 and FIG. 4, the visual recognition system 23 includes four image capturing devices 231 and 232, e.g. photo cameras, video cameras, and so on, and light source (not shown) required for the image capturing devices 231 and 232 to capture images, which are disposed in the housing 21. The four image capturing devices 231 and 232 are fixed relative to the housing 21 and arranged aslant to shoot downward and aslant toward about the same position, so that the fields of view of the four image capturing devices 231 and 232 are connected with each other into a relatively larger field of view 234, also called FOV When the end effector 226 carrying the device under test 50 is located at the position for being shot by the visual recognition system 23 and thereby the four image capturing devices 231 and 232 can shoot toward the end effector 226 to capture the image of the device under test 50, as shown in FIG. 4, the two image capturing devices 231 are located correspondingly to a side of the end effector 226 and the two image capturing devices 232 are located correspondingly to the other side of the end effector 226. The field of view 234 provided by such arrangement can make the device under test 50 completely located in the field of view 234 of the four image capturing devices 231 and 232, so that the image of the entire device under test 50 can be captured. Alternatively, the visual recognition system 23 may include three image capturing devices 231, 232 and 233 evenly distributed at intervals of 120 degrees on an imaginary plane, as shown in FIG. 5. When the three image capturing devices 231, 232 and 233 capture the image of the device under test 50, the image capturing devices 231 and 232 are located correspondingly to two sides of the end effector 226 respectively and the image capturing device 233 is located correspondingly to an end of the end effector 226. The field of view 234 provided by such arrangement can also make the device under test 50 completely located in the field of view 234 of the three image capturing devices 231-233, so that the image of the entire device under test 50 can be captured. It takes only the visual recognition system 23 shown in FIG. 3 and FIG. 4 as an example fir the following description.

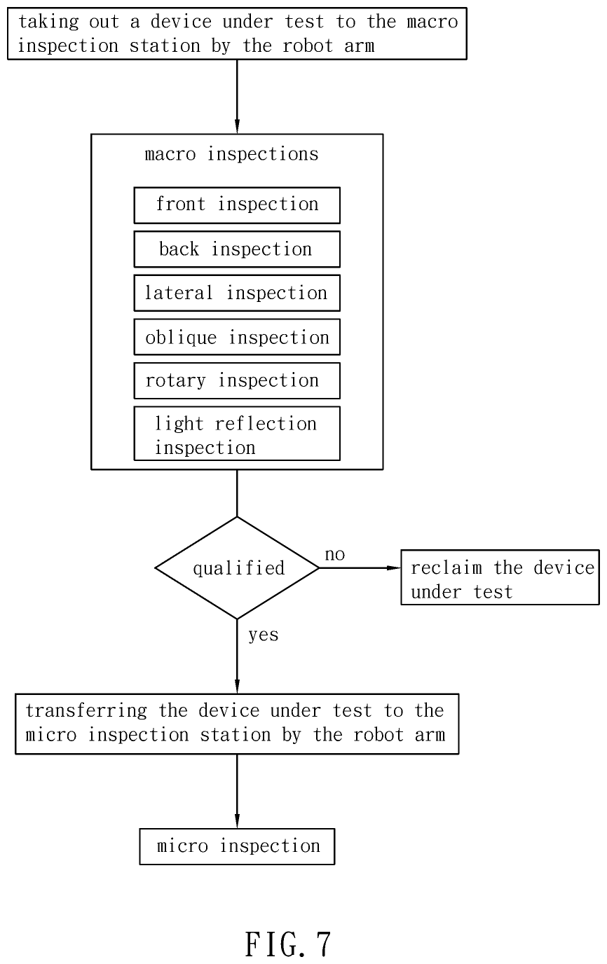

The macro and micro inspection apparatus 10 of the present invention is adapted to implement an inspection method as shown in FIG. 7, The inspection method includes the following steps.

a) A device under test 50 is taken out from a supply cassette 42 of the device under test storage station 40 to the macro inspection station 20 by the end effector 226 of the robot arm 22.

b) The image of the device under test 50 is captured by the image capturing devices 231 and 232 of the visual recognition system 23 for a macro inspection to be performed.

c) The device under test 50 is rotated by the robot arm 22, and the image of the device under test 50 which has been rotated is captured by the image capturing devices 231 and 232 of the visual recognition system 23 for another macro inspection to be performed.

It can be known from the aforementioned steps b) and c) that the macro inspection station 20 is used for performing at least two different macro inspections to the device under test 50, In the step b), the device under test 50 is shot by the image capturing devices 231 and 232 right after entering the macro inspection station 20. At this time, it is usually, but unlimited to be, the front of the device under test 50 to be shot by the image capturing devices 231 and 232 for performing a front inspection, that is the status as shown in FIG. 3 and FIG. 4. In the step c), by the robot arm 22 rotating the device under test 50, in particular primarily, but unlimited to, the end effector 226 rotating about the fifth imaginary axis L5, the visual recognition system 23 can shoot the parts of the device under test 50 other than the front thereof for performing the associated inspections, such as back inspection, lateral inspection, oblique inspection, rotary inspection, light refection inspection, and so on.

d) If the result of the macro inspections performed by the visual recognition system 23 is the device under test 50 is determined to be unqualified, the device under test 50 is put back to the reclaim cassette 43 of the device under test storage station 40 by the robot arm 22. If the result of the macro inspections performed by the visual recognition system 23 is the device under test 50 is determined to be qualified, the device under test 50 is transferred to the micro inspection station 30 by the robot arm 22, for a micro inspection to be performed to the device under test 50 in the micro inspection station 30. The end effector 226 of the robot arm 22 will take out the device under test 50 after the micro inspection is accomplished, and the robot arm 22 will send the inspected device under test 50 back into the supply cassette 42 of the device under test storage station 40.

As a result, the robot arm 22 can simulate the conventional macro inspection actions the quality inspector performs to the device under test 50, such as displacing, tilting, rotating, and so on, and cooperate with the visual recognition system 23 to perform the macro inspections to the device under test 50. That can not only avoid the problems of missed inspection, false inspection, wafer falling, wafer collision, and so on, which may be caused by manual inspection, but also steadily repeat the same macro inspection actions to attain great inspection effect. Besides, the macro and micro inspection apparatus 10 of the present invention only needs the robot arm 22 to transfer the device under test 50 for connecting the procedures of supplying, reclaiming, macro inspection and micro inspection, thereby saving time for transferring, classification, collection and waiting between different procedures. The device under test 50 qualified by the macro inspections can be quickly transferred to the micro inspection station 30 by the robot arm 22 for the micro inspection, without the requirement of additional classification, collection and waiting, so the transferring time is reduced, Besides, without the requirement of classifying, collecting and waiting stations, it takes up relatively less space. The device under test 50 unqualified by the macro inspections can be also quickly transferred by the robot arm 22 to the reclaim cassette 43, without the requirement of additional classification, collection and waiting, so the transferring time is reduced. Besides, without the requirement of classifying, collecting and waiting stations, it takes up relatively less space. Therefore, the macro and micro inspection apparatus 10 of the present invention is simple in structure, space-saving, and capable of bringing high inspection efficiency and machine utilization.

As shown in FIG. 1, the visual recognition system 23 in this embodiment may, but unlimited to, be disposed between the aforementioned middle position P and the device under test storage station 40. It is to be mentioned that the middle position P mentioned in the present invention is unlimited to be located right in the middle of the path of the robot arm 22 moving along the first horizontal axis (X-axis), as long as the robot arm 22 can move from the middle position P toward the two opposite directions of the first horizontal axis, i.e. the positive direction of X-axis and the negative direction of X-axis. In other words, the middle position P may be any position on the path other than two ends of the path. In this way, right after the device under test 50 is taken out by the robot arm 22 from the device under test storage station 40 and enters the macro inspection station 20, the device under test 50 is located at the position corresponding to the visual recognition system 23 and thereby the macro inspection can be performed immediately. If the device under test 50 is unqualified based on the macro inspection result, the robot arm 22 can quickly put the device under test 50 back to the device under test storage station 40, such that the inspection efficiency is further raised.

Further speaking, the position of the visual recognition system 23 in this embodiment is primarily arranged in a way that the robot arm requires the least time for movement. In FIG. 1, the visual recognition system 23 is positioned between the device under test storage station 40 and the robot arm 22. This positional arrangement enables the follow-up movement of the robot arm 22 to the micro inspection station 30 relatively better continuity of action, bringing relatively better time benefit ratio. Comparatively, if the visual recognition system 23 is disposed between the robot arm 22 and the micro inspection station 30 or between the robot arm 22 and the third side 26 or the fourth side 27, after taking out the device under test from the device under test storage station 40, the robot arm 22 should be firstly moved to the position correspondingly to the visual recognition system 23 for the macro inspections to be performed to the device under test, which means the action of the robot arm 22 stops at this time, and after that the robot arm 22 is moved to the micro inspection station 30, Such moving process consumes longer time when compared with the moving process required for the arrangement as shown in FIG. 1.

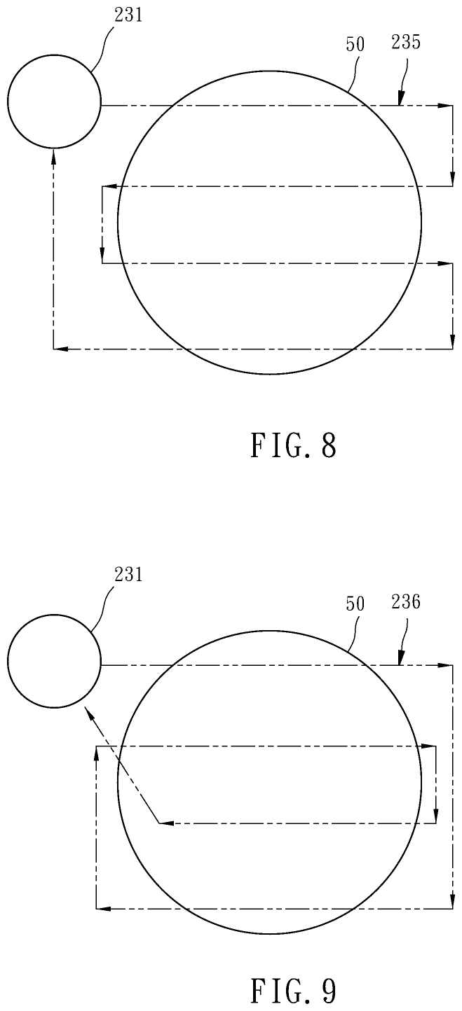

In the present invention, the amount of the image capturing devices of the visual recognition system 23 is unlimited. It is unlimited to arrange three or four image capturing devices as shown in FIG. 3 to FIG. 5 to provide the field of view 234 capable of covering the entire device under test 50. For the case that the field of view of the image capturing device cannot cover the entire device under test 50, such as the case arranged with only one image capturing device 231 as shown in FIG. 8 and FIG. 9, the image capturing device 231 may be moved along an S-shaped path 235 as shown in FIG. 8 or a squire path 236 as shown in FIG. 9, to shoot the device under test 50 in a scanning manner. Alternatively, the image capturing device 231 may be fixed and unmovable, but the device under test 50 is moved by the end effector 226 of the robot arm 22 to attain the same effect of shooting in the scanning manner.

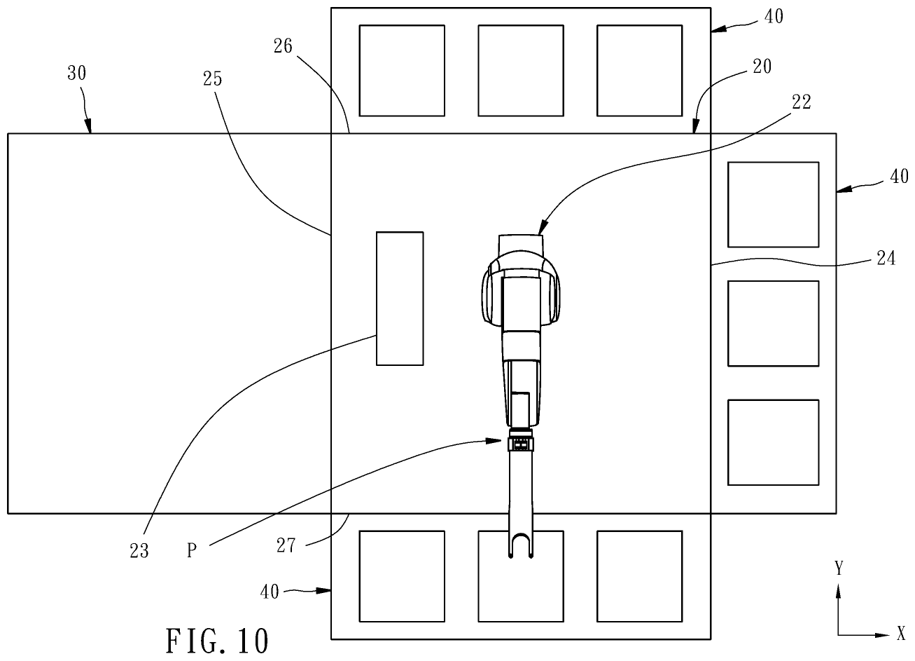

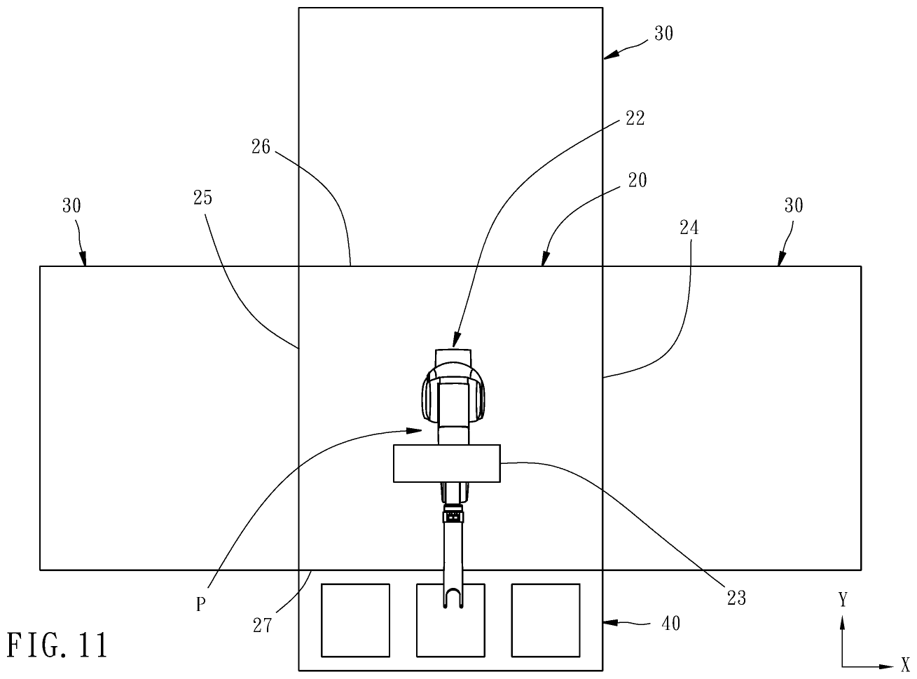

In the present invention, the amount of the micro inspection station 30 and the amount of the device under test storage station 40 are also unlimited. In this embodiment, the macro inspection station 20 has first to fourth sides 24-27, so the macro inspection station 20 can serve as the center of the apparatus to connect the micro inspection station 30 and device under test storage station 40 totaling up to four at most, such as the arrangements in second and third preferred embodiments of the present invention as shows in FIG. 10 and FIG. 11, which will be specified in the following.

In the second preferred embodiment as shown in FIG. 10, a micro inspection station 30 is disposed on the second side 25 of the macro inspection station 20, and three device under test storage stations 40 are disposed on the first side 24, the third side 26 and the fourth side 27 respectively. The visual recognition system 23 is disposed between the aforementioned middle position P and the micro inspection station 30. Such arrangement makes the three device under test storage stations 40 distanced from the position corresponding to the visual recognition system 23 approximately equally, which benefits minimizing the time required for the macro inspections.

Further speaking, the visual recognition system 23 in this embodiment is arranged in a concept of the position certainly on the path of the robot arm 22. In FIG. 10, when the robot arm 22 is moved from anyone of the three device under test storage stations 40 to the micro inspection station 30, it will pass the position corresponding to the visual recognition system 23, so such positional arrangement minimizes the time of the movement of the robot arm. For example, if the visual recognition system 23 is disposed between the robot arm 22 and the first side 24, after taking out the device under test from the device under test storage station 40 located on the third side 26 or fourth side 27, the robot arm should firstly rotate for 90 degrees to the position corresponding to the visual recognition system 23 for the macro inspection and then rotate for 180 degrees to the micro inspection station 30. Such moving process consumes additional time of rotating for 180 degrees to the micro inspection station 30 when compared with the moving process required for the arrangement as shown in FIG. 10. Therefore, the positional arrangement of the visual recognition system 23 in the embodiment shown in FIG. 10 can reduce time for the inspection. In the third preferred embodiment as shown in FIG. 11, a device under test storage station 40 is disposed on the fourth side 27 of the macro inspection station 20, and three micro inspection stations 30 are disposed on the first to third sides 24-26 respectively. The visual recognition system 23 is disposed between the robot arm 22 and the device under test storage station 40. This arrangement is convenient for the robot arm 22 to quickly move the device under test taken out from the device under test storage station 40 to the position corresponding to the visual recognition system 23 and quickly put the device under test unqualified by the macro inspections back to the device under test storage station 40. As the above explanation for the arrangement shown in FIG. 10, the visual recognition system 23 in FIG. 11 is also arranged at the position the robot arm 22 will certainly pass. Besides, similar to the arrangement as shown in HG. 1, the position of the visual recognition system 23 in FIG. 11 also enables the movement of the robot arm 22 to the micro inspection station 30 relatively better continuity of action, thereby raising the inspection efficiency.

The macro and micro inspection apparatus 10 of the present invention may be provided with the micro inspection station 30 and device under test storage station 40 on any two sides, any three sides or all the four sides of the macro inspection station 20, as long as at least one side of the first to four sides 24-27 is provided with the device under test storage station 40 and at least another side of the first to fourth sides 24-27 is provided with the micro inspection station 30. According to different amounts and different positional arrangement, there are many possible constitutions. Therefore, according to the use requirements and the use environment, the most appropriate arrangement can be made to improve the machine utilization and production capacity. For the arrangements with a plurality of device under test storage stations 40, the device under test storage stations 40 may store the devices under test of different sizes, so that the devices under test of the same kind but different sizes can be mixed and supplied at the same time, which can save the time of stopping and waiting for changing the supply cassette.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A macro and micro inspection apparatus comprising:
a macro inspection station;
a device under test storage station disposed on a side of the macro inspection station; and
a micro inspection station disposed on another side of the macro inspection station;
wherein, the macro inspection station comprises a housing, a robot arm, and a visual recognition system; the robot arm comprises an end effector adapted for carrying and turning over a device under test; the robot arm is disposed in the housing in a way that the end effector enables to enter the device under test storage station and the micro inspection station; the visual recognition system comprises at least one image capturing device disposed in the housing to enable shooting toward the end effector for capturing an image of the device under test.

2. The macro and micro inspection apparatus as claimed in claim 1, wherein the visual recognition system is disposed between the robot arm and the device under test storage station.

3. The macro and micro inspection apparatus as claimed in claim 1, wherein the macro and micro inspection apparatus is defined with a horizontal axis; the macro inspection station has a first side and a second side, which face toward two opposite directions of the horizontal axis; the device under test storage station and the micro inspection station are disposed on the first side and the second side respectively; the robot arm is movable relative to the housing along the horizontal axis from a middle position toward the two opposite directions.

4. The macro and micro inspection apparatus as claimed in claim 3, wherein the visual recognition system is disposed between the middle position and the device under test storage station.

5. The macro and micro inspection apparatus as claimed in claim 1, wherein the macro and micro inspection apparatus is defined with a first horizontal axis and a second horizontal axis perpendicular to the first horizontal axis; the macro inspection station has a first side and a second side, which face toward two opposite directions of the first horizontal axis, and a third side and a fourth side, which face toward two opposite directions of the second horizontal axis; the robot arm is movable relative to the housing along the first horizontal axis from a middle position toward the two opposite directions of the first horizontal axis; among the first side, the second side, the third side and the fourth side of the macro inspection station, at least one said side is provided with the device under test storage station, and at least another said side is provided with the micro inspection station.

6. The macro and micro inspection apparatus as claimed in claim 5, wherein the first side and the second side of the macro inspection station are provided with the device under test storage station and the micro inspection station, respectively; at least one of the third side and the fourth side is also provided with the device under test storage station; the visual recognition system is disposed between the middle position and the micro inspection station.

7. The macro and micro inspection apparatus as claimed in claim 5, wherein the first side and the second side of the macro inspection station are each provided with one said micro inspection station; one of the third side and the fourth side is provided with the device under test storage station; the visual recognition system is disposed between the robot arm and the device under test storage station.

8. The macro and micro inspection apparatus as claimed in claim 1, wherein the visual recognition system comprises four said image capturing devices arranged aslant; when the four image capturing devices capture the image of the device under test, two of the image capturing devices are located correspondingly to a side of the end effector, and the other two said image capturing devices are located correspondingly to another side of the end effector, so that the device under test is completely located in a field of view of the four image capturing devices.

9. The macro and micro inspection apparatus as claimed in claim 1, wherein the visual recognition system comprises three said image capturing devices arranged aslant; when the three image capturing devices capture the image of the device under test, two of the image capturing devices are located correspondingly to two sides of the end effector respectively, and the other said image capturing device is located correspondingly to an end of the end effector, so that the device under test is completely located in a field of view of the three image capturing devices.

10. The macro and micro inspection apparatus as claimed in claim 1, wherein the robot arm comprises a base movable relative to the housing along a horizontal axis, a first rotary arm attached to the base rotatably about a first imaginary axis, a second rotary arm attached to the first rotary arm rotatably about a second imaginary axis perpendicular to the first imaginary axis, a third rotary arm attached to the second rotary arm rotatably about a third imaginary axis parallel to the second imaginary axis, and a fourth rotary arm attached to the third rotary arm rotatably about a fourth imaginary axis parallel to the second imaginary axis; the end effector is attached to the fourth rotary arm rotatably about a fifth imaginary axis perpendicular to the fourth imaginary axis.

11. The macro and micro inspection apparatus as claimed in claim 1, wherein the end of the robot arm comprises a fork-shaped board; the fork-shaped board comprises a carrying surface, and a plurality of vacuum suction holes provided on the carrying surface for attaching the device under test on the carrying surface by vacuum suction.

12. The macro and micro inspection apparatus as claimed in claim 1, wherein the end effector of the robot arm comprises a supporting seat, and a carrying plate disposed on an end portion of the supporting seat; the carrying plate is provided on a carrying surface thereof with a plurality of vacuum suction holes for attaching the device under test on the carrying surface by vacuum suction.

13. The macro and micro inspection apparatus as claimed in claim 1, wherein the micro inspection station is an automated optical inspection system.

14. An inspection method using the macro and micro inspection apparatus as claimed in claim 1, the inspection method comprising the steps of:
taking out a said device under test from the device under test storage station to the macro inspection station by the end effector of the robot arm;
capturing an image of the device under test by the image capturing device of the visual recognition system to perform a macro inspection;
rotating the device under test by the robot arm, and capturing another image of the device under test which has been rotated by the image capturing device of the visual recognition system to perform another macro inspection; and
if a result of the macro inspections performed by the visual recognition system is the device under test is determined to be unqualified, putting the device under test back to the device under test storage station by the robot arm; if the result of the macro inspections performed by the visual recognition system is the device under test is determined to be qualified, transferring the device under test to the micro inspection station by the robot arm for performing a micro inspection to the device under test in the micro inspection station.

15. The inspection method as claimed in claim 14, wherein the macro inspections performed to the device under test by the macro inspection station comprise at least two of a front inspection, a back inspection, a lateral inspection, an oblique inspection, a rotary inspection and a light refection inspection.

16. The inspection method as claimed in claim 14, wherein the macro and micro inspection apparatus comprises a plurality of said device under test storage stations disposed on different sides of the macro inspection station; the device under test storage stations store the devices under test of different sizes.

17. The inspection method as claimed in claim 14, wherein when the image of the device under test is captured by the image capturing device of the visual recognition system, the image capturing device and the end effector of the robot arm are moved relative to each other for the device under test to be shot by the image capturing device in a scanning manner.
